(19) United States
(12) Patent Application Publication
(10) Pub. No.: US 2015/0079701 A1
(43) Pub. Date: Mar. 19, 2015

(54) SEMICONDUCTOR DEVICE MANUFACTURING METHOD AND MANUFACTURING APPARATUS

(71) Applicant: KABUSHIKI KAISHA TOSHIBA, Tokyo (JP)

(72) Inventor: Daisuke YAMASHITA, Ishikawa (JP)

(73) Assignee: KABUSHIKI KAISHA TOSHIBA, Tokyo (JP)

(21) Appl. No.: 14/194,409

(22) Filed: Feb. 28, 2014

(30) Foreign Application Priority Data
Sep. 17, 2013 (JP) 2013-191682

(51) Int. Cl. H01L 21/66; H01L 21/67; H01L 21/687

(52) U.S. Cl. CPC H01L 22/26; H01L 21/68764; H01L 21/67017; H01L 21/67069; H01L 21/6708
USPC 438/5; 438/14; 156/345.21; 156/345.33; 156/345.15; 156/345.24; 118/712; 118/728; 118/729; 118/313; 134/99.1; 134/34; 134/18; 134/37; 134/33

(57) ABSTRACT

A manufacturing apparatus includes a chuck for contacting a peripheral portion of a workpiece. The apparatus includes a nozzle to eject a process fluid (liquid or gas) toward a first surface while the workpiece is in contact with the chuck. The apparatus also includes a plate having an opening configured such that a support fluid (liquid or gas) can be ejected toward a second surface of the workpiece while the workpiece is in contact with the chuck. In an example, the support fluid can be used to counteract a displacement of the interior portion in the direction perpendicular to the plane of the workpiece due to, for example, gravity and/or hydrostatic pressure of the process fluid.

### CROSS-REFERENCE TO RELATED APPLICATION

This application is based upon and claims the benefit of priority from Japanese Patent Application No. 2013-191682, filed Sep. 17, 2013, the entire contents of which are incorporated herein by reference.

### FIELD

Embodiments described herein relate to semiconductor device manufacturing methods and manufacturing apparatuses.

### BACKGROUND

Generally, a discrete semiconductor has a device structure formed in the thickness direction of a wafer. Thus, when discrete semiconductors are manufactured, it may be necessary to grind the backside of a wafer to make the wafer thinner while not applying pressure that causes the wafer to break or crack. However, as a wafer is made thinner there is a reduction in rigidity and the wafer may even warp or bend under its own weight. Such thin wafers are difficult to handle during subsequent manufacturing processes.

### DESCRIPTION OF THE DRAWINGS

FIG. 1 is a diagram of a semiconductor device manufacturing apparatus according to a first embodiment.

FIG. 2A is a diagram of a semiconductor device manufacturing apparatus according to a comparative example.

FIG. 2B is a partially-enlarged view showing a deformed state of a thin-sheet portion of a wafer.

FIG. 3 is a diagram of a semiconductor device manufacturing apparatus according to a second embodiment.

FIG. 4 is a plan view showing a plate in a semiconductor device manufacturing apparatus according to a third embodiment.

FIG. 5A is a diagram illustrating an operation of a semiconductor device manufacturing apparatus according to a fourth embodiment.

FIG. 5B is a diagram illustrating the operation of the semiconductor device manufacturing apparatus according to the fourth embodiment.

FIG. 6 is a diagram (part (a)) illustrating a semiconductor device manufacturing apparatus according to a fifth embodiment and a graph (part (b)) showing the in-plane distribution of hydraulic pressure with the location in a wafer plane on the horizontal axis and with the hydraulic pressure of a liquid on the vertical axis.

### DETAILED DESCRIPTION

According to the exemplary embodiments, there is provided a semiconductor device manufacturing method and a manufacturing apparatus.

In an embodiment, a manufacturing apparatus includes a chuck for contacting a peripheral portion of a workpiece, such as a semiconductor wafer. The apparatus includes a nozzle to eject a process fluid (liquid or gas) toward a first surface while the workpiece is in contact with the chuck. The process fluid may be, for example, for cleaning, etching, or coating the workpiece or portions thereof. The apparatus also includes a plate having an opening configured such that a support fluid (liquid or gas) can be ejected toward a second surface of the workpiece while the workpiece is in contact with the chuck. In an example, the support fluid can be used to counteract a displacement (warpage) of the interior portion in the direction perpendicular to the plane of the workpiece due to, for example, gravity and/or hydrostatic pressure of the process fluid.

An example embodiment concerns a wafer processing technique in which a rim portion (peripheral portion) of the wafer is left with an original thickness (i.e., is not ground/thinned) while an interior portion of the wafers is ground/thinned. The interior portion is, in general, surrounded by the rim portion within the wafer plane. The peripheral portion is thus thicker than the interior portion in a direction perpendicular to the plane of the wafer. By leaving the rim portion with a thickness greater than the interior portion this technique improves rigidity of the entire wafer, even those portions which may have been thinned by grinding or the like, allowing the wafer to be handled in subsequent process steps without excessive warpage and/or breaking. This wafer processing technique is exemplary and is not required of all embodiments of the present disclosure.

In general, according to one embodiment, there is provided a semiconductor device manufacturing apparatus for processing a first surface of a thin-sheet portion other than a rim portion of a wafer with the rim portion thicker than the thin-sheet portion. The manufacturing apparatus includes chucks for holding the rim portion, a nozzle for ejecting a first fluid toward the first surface, and a plate provided with an ejection opening through which a second fluid is ejected toward a second surface of the thin-sheet portion.

In general, according to one embodiment, a semiconductor device manufacturing method is a method for processing a first surface of a thin-sheet portion other than a rim portion of a wafer with the rim portion thicker than the thin-sheet portion. The manufacturing method includes holding the rim portion, and ejecting a first fluid toward the first surface while ejecting a second fluid toward a second surface of the thin-sheet portion.

Hereinafter, with reference to the drawings, example embodiments will be described.

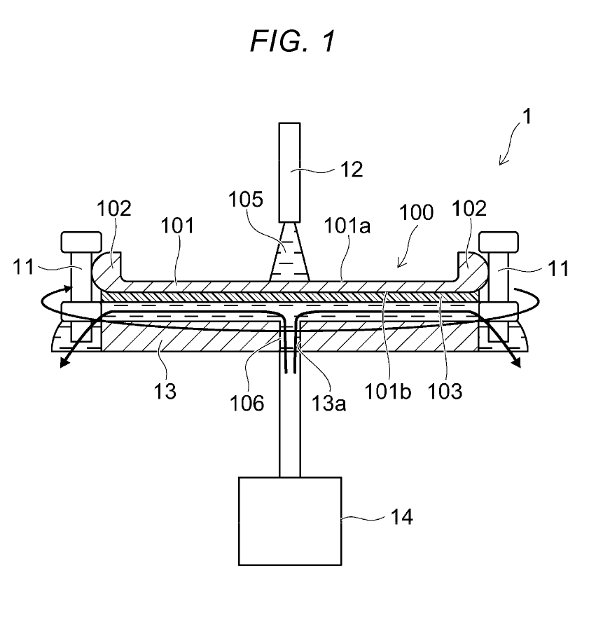

FIG. 1 is a diagram illustrating a semiconductor device manufacturing apparatus according to a first embodiment.

As shown in FIG. 1, a semiconductor device manufacturing apparatus 1 according to the embodiment is an apparatus for performing wet processing on a wafer 100 in order to manufacture discrete semiconductor devices such as insulated gate bipolar transistors (IGBT) and vertical metal-oxide-semiconductor field-effect transistors (MOSFET), for example. The manufacturing apparatus 1 is a single-wafer processing apparatus, and is at least one of a wet-etching apparatus, a cleaning apparatus, or a coating apparatus, for example.

First, the wafer 100 to be processed by the manufacturing apparatus 1 will be described.

The wafer 100 is a silicon wafer, for example, on which semiconductor devices are to be formed. In the wafer 100, a thin-sheet portion 101 is made thinner than an initial, original wafer thickness by grinding and a rim portion 102 as a peripheral edge portion of the wafer 100 is not ground and is left with the original wafer thickness.

The thin-sheet portion 101 is a portion other than the rim portion 102 of the wafer 100, and has a thickness of 100 to 250 μm, for example. The rim portion 102, in this example, has an annular shape, and is thicker than the thin-sheet portion 101. With the rim portion 102 constituting a reinforcing portion, the entire of the wafer 100 has overall improved rigidity as compared to a wafer that having no rim portion. Inclusion of rim portion 102 can prevent wafer 100 from warping under its own weight. In wafer 100, an upper surface 101a of the thin-sheet portion 101 is ground, and a lower surface 101b is not ground, for example. A back side grinding (BSG) tape 103 is attached to an entire lower surface of the wafer 100 including the lower surface 101b.

A manufacturing apparatus 1 of an embodiment is provided with a plurality of chucks 11. The chucks 11 hold the wafer 100 by the rim portion 102, and the chucks 11 may be used to rotate the wafer 100. The chucks 11 contact only the rim portion 102, and do not contact the upper surface 101a and the lower surface 101b of the thin-sheet portion 101. Thus, the upper surface 101a and the lower surface 101b of the thin-sheet portion 101 may be subjected to wet processing. The chucks 11, in some embodiments, contact only a vertical surface (perpendicular to the wafer plane) of the rim portion 10. The chucks 11 may be disposed so as to contact a periphery of wafer 100. Chucks 11 may be referred to as chuck portions 11. In some embodiments, wafer 100 may be held by a single chuck 11 which itself contacts different points of rim portion 102.

The manufacturing apparatus 1 is also provided with a nozzle 12 for ejecting a liquid 105 toward the upper surface 101a of the thin-sheet portion 101. The liquid 105 is a processing liquid for performing wet processing on the upper surface 101a of the thin-sheet portion 101, and may be a chemical solution for cleaning the upper surface 101a of the thin-sheet portion 101, such as dilute hydrofluoric acid (dHF), NC-2, SC-1, SC-2, or a sulfuric acid-hydrogen peroxide (H₂O₂) mixture (SPM), for example, or may be a chemical solution for etching the upper surface 101a, such as a mixed solution of nitric acid (HNO₃) and hydrofluoric acid (HF), or FEP, for example, or may be a chemical solution for rinsing the upper surface 101a such as de-ionized water (DIW), for example, or may be a resist material for forming a resist film on the upper surface 101a.

Further, the manufacturing apparatus 1 is provided with a plate 13. The plate 13 is arranged below the wafer 100 at a position opposite to the lower surface 101b. The plate 13 is formed with an ejection opening 13a for ejecting a liquid 106 toward the lower surface 101b. Since the BSG tape 103 is attached to the lower surface of the wafer 100 as described above, the liquid 106 contacts the BSG tape 103, applying an upward force to the thin-sheet portion 101 via the BSG tape 103. In the embodiment, the ejection opening 13a is formed only in one location where the liquid 106 is ejected vertically toward the center of the wafer 100. The manufacturing apparatus 1 is also provided with a liquid supply apparatus 14 for supplying the liquid 106 to the ejection opening 13a. The liquid 106 is a supporting fluid for supporting the wafer 100 against warpage, and is DIW, for example. Since the thin-sheet portion 101 is generally very thin and potentially fragile, it is usually not impossible to provide a support member that contacts the lower surface 101b, and thus there is an unfilled space left below the thin-sheet portion 101 and the chuck 11 which may be filled with liquid 106 supplied by liquid supply apparatus 14 during processing steps of wafer 100.

Next, the operation of the semiconductor device manufacturing apparatus 1 will be described.

As shown in FIG. 1, first, the chucks 11 contact the rim portion 102 of the wafer 100, and rotate the wafer 100. In this state, the liquid 105 is ejected from the nozzle 12 toward a central portion of the upper surface 101a. Simultaneously, the liquid supply apparatus 14 ejects the liquid 106 through the ejection opening 13a in the plate 13 toward a central portion of the lower surface 101b. For example, the flow rate or pressure of the liquid 106 can be set to be higher than the flow rate or pressure of the liquid 105.

The liquid 105 contacts the central portion of the upper surface 101a, spreading toward the rim portion 102 by the centrifugal force accompanying the rotation of the wafer 100. Thus, the upper surface 101a is wet-processed by the liquid 105. For example, the upper surface 101a is cleaned, etched, or rinsed by the liquid 105. However, at this time, the hydraulic pressure of the liquid 105 and the weight of the liquid 105 accumulating on the thin-sheet portion 101 apply a downward force to the thin-sheet portion 101. On the other hand, the liquid 106 ejected from the ejection opening 13a contacts the central portion of the lower surface 101b, applying a hydraulic pressure to the lower surface 101b via the BSG tape 103. Thus, an upward force is applied to the thin-sheet portion 101 to counter the downward force caused by liquid 105.

According to the embodiment, the upward force applied to the thin-sheet portion 101 by the hydraulic pressure of the liquid 106 counteracts the downward force applied to the thin-sheet portion 101 by the hydraulic pressure and the weight of the liquid 105, thus allowing the thin-sheet portion 101 to be supported without bringing a solid member into contact with the thin-sheet portion 101. Thus, the thin-sheet portion 101 is prevented from warpage, and the thin-sheet portion 101 may be kept flat. As a result, by the force applied by the liquid 105, the thin-sheet portion 101 may be prevented from warpage and a crack or a break in the thin-sheet portion 101 may be prevented. Further, it may be prevented that warpage of the thin-sheet portion 101 causes non-uniform distribution of the liquid 105 on the thin-sheet portion 101, resulting in non-uniform processing with the liquid 105. As a result, the yield of wet processing with the liquid 105 may be increased.

The type of the liquid 105 and a type of the liquid 106 may be chosen as desired. For example, liquid 105 and liquid 106 may be the same or different types and may be selected according to the wet processing to be carried out. For example, when a chemical solution for cleaning is used as the liquid 105, the same chemical solution for cleaning may be used for the liquid 106 to clean the lower surface 101b simultaneously with the upper surface 101a of the thin-sheet portion 101. Further, the physical properties such as viscosities and specific gravities of the liquids 105 and 106 may be made uniform (though this is not a necessity), thus facilitating the control of pressure. Alternatively, when a chemical solution for cleaning is used as the liquid 105, pure water may be used for the liquid 106 to rinse the lower surface 101b to which the BSG tape 103 is attached, and to help prevent the chemical solution of the liquid 105 from leaking to the lower surface 101b.

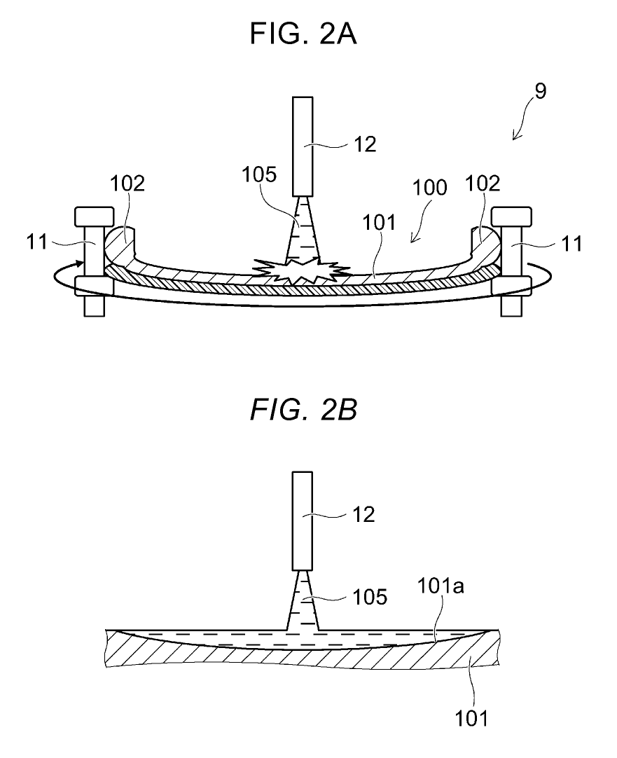

FIG. 2A is a diagram illustrating a semiconductor device manufacturing apparatus according to a comparative example. FIG. 2B is a partially enlarged view showing a deformed state of a thin-sheet portion of a wafer.

As shown in FIG. 2A, in a manufacturing apparatus 9 according to the comparative example, a plate 13 and a liquid supply apparatus 14 (see FIG. 1) are not provided, and a supporting liquid 106 (see FIG. 1) is not ejected toward a lower surface 101b.

Therefore, the thin-sheet portion 101 of a wafer 100 warps to be convex downward by the hydraulic pressure and the weight of a liquid 105. Since the wafer 100 is provided with a thick rim portion 102, thus achieving a certain degree of rigidity, the wafer 100 does not warp largely by its own weight. However, the thin-sheet portion 101 is thinner than the rim portion 102, and therefore may warp significantly when a downward force is applied to a central portion of the thin-sheet portion 101 by the liquid 105. This may cause a crack in the thin-sheet portion 101, or cause a break in the thin-sheet portion 101. Further, as shown in FIG. 2B, the thin-sheet portion 101 warping to be convex downward causes the amount of the liquid 105 accumulating on the central portion of the thin-sheet portion 101 to be greater than the amount of the liquid 105 accumulating on a peripheral portion of the thin-sheet portion 101, thus reducing the in-plane uniformity of processing. When the liquid 105 is an etchant, for example, etching at the central portion of the thin-sheet portion 101 may be relatively enhanced while etching at the peripheral portion is relatively suppressed. As a result, the yield of semiconductor devices may be reduced by the across-wafer process variation.

By contrast, according to the first embodiment, the liquid 106 is ejected from the opposite side of the liquid 105 with the thin-sheet portion 101 therebetween, whereby the thin-sheet portion 101 is supported by the liquid 106, and may be prevented from warpage.

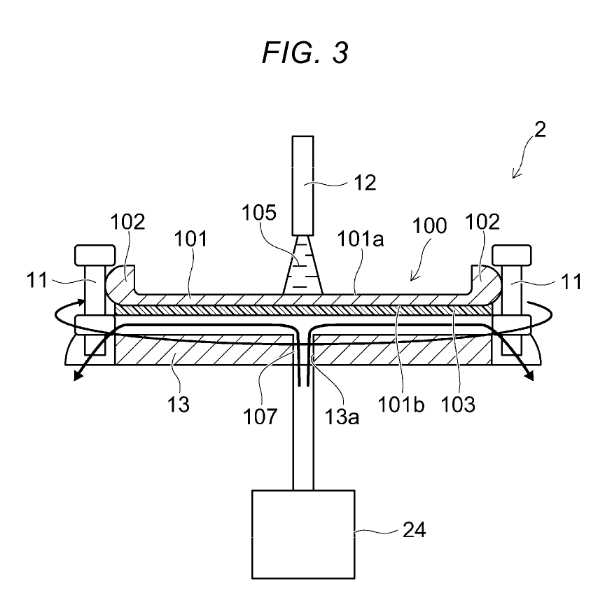

FIG. 3 is a diagram illustrating a semiconductor device manufacturing apparatus according to a second embodiment.

As shown in FIG. 3, in a manufacturing apparatus 2 according to the embodiment, a gas supply apparatus 24 is provided instead of the liquid supply apparatus 14 (see FIG. 1). Thus, a gas 107 is jetted toward a lower surface 101b of a thin-sheet portion 101 of a wafer 100. The gas 107 may be a nitrogen gas (N₂), for example. The gas 107 is jetted under conditions where the Bernoulli's effect is not substantial, in order to avoid a suction effect to be caused by flow of the gas 107.

In this second embodiment, as in the first embodiment, the thin-sheet portion 101 is supported by the pressure of the gas 107, and the thin-sheet portion 101 may be prevented from warpage. Further, the gas 107 may prevent a liquid 105 from leaking to the lower surface 101b side. Due to this, when a resist material is used as the liquid 105, and a tape not resistant to an organic solvent is used as a BSG tape 103, the resist material may be prevented from contacting the BSG tape 103. Further, a gas may be jetted from a nozzle 12 instead of the liquid 105. Due to this, the wafer 100 after wet processing may be dried. In this case, by using the gas 107 instead of the liquid 105 as a fluid for supporting the thin-sheet portion, both sides of the wafer 100 may be dried simultaneously. The configuration, operation, and effects other than those above in the second embodiment are otherwise similar to those in the first embodiment.

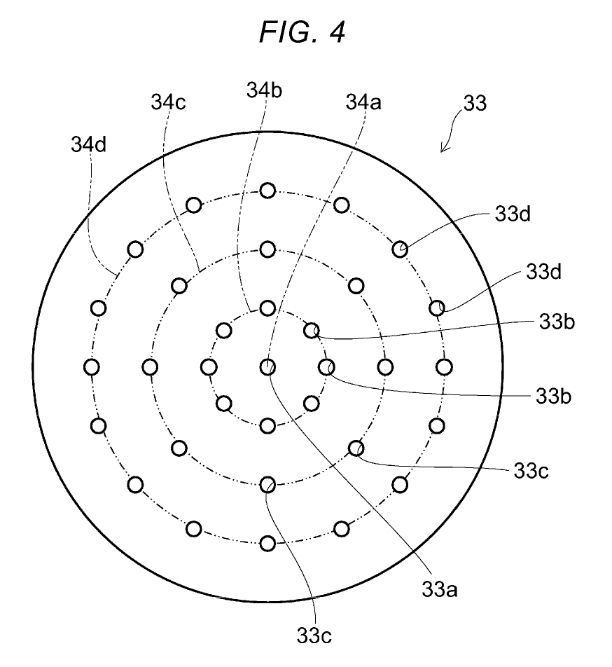

FIG. 4 is a plan view showing a plate in a semiconductor device manufacturing apparatus according to a third embodiment.

As shown in FIG. 4, in the manufacturing apparatus according to the third embodiment, a plate 33 is provided instead of the plate 13 (see FIG. 1). In the plate 33, a plurality of ejection openings 33a to 33d are formed. The ejection opening 33a is arranged at the center 34a of the plate 33. The ejection openings 33b to 33d are arranged concentrically along imaginary concentric circles 34b to 34d with the center 34a as the center.

According to the embodiment, by ejecting a liquid 106 from the plurality of ejection openings 33a to 33d, the liquid 106 may be ejected toward a plurality of areas on a lower surface 101b of a thin-sheet portion 101 as well as a central portion of the lower surface 101b. Further, by making the ejection openings 33a to 33d different from each other in diameter, the flow rates of the liquid 106 ejected from the ejection openings 33a to 33d may be made different from each other. Alternatively, by providing appropriate adjustments on the lower surface side of the plate 33, the pressures of the liquid 106 ejected from the ejection openings 33a to 33d may be made different from each other. By controlling the flow rates or pressures of the liquid 106 in this manner, the in-plane distribution of force the liquid 106 applies to the thin-sheet portion 101 may be optimized, and the shape of the thin-sheet portion 101 may controlled more precisely. The configuration, operation, and effects other than those above in the embodiment are otherwise similar to those in the first embodiment.

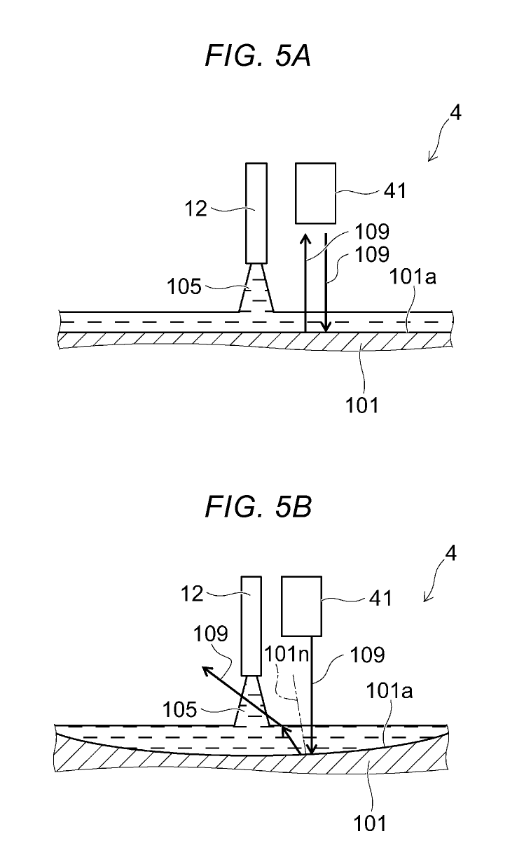

FIGS. 5A and 5B are diagrams illustrating the operation of a semiconductor device manufacturing apparatus according to a fourth embodiment.

As shown in FIGS. 5A and 5B, in a semiconductor device manufacturing apparatus 4 according to the embodiment, in addition to the configuration of the manufacturing apparatus 1 (see FIG. 1) according to the first embodiment, a laser sensor 41 is provided. The laser sensor 41 is arranged above a wafer 100 at a position where laser light 109 is emitted toward a portion other than the center of a thin-sheet portion 101 from a direction perpendicular to an upper surface 101a. In FIGS. 5A and 5B, device components other than a nozzle 12, a liquid 105, the thin-sheet portion 101 of the wafer, and the laser sensor 41 are not specifically depicted for sake of clarity.

In the manufacturing apparatus 4, the laser sensor 41 emits the laser light 109 toward the thin-sheet portion 101 (downward arrow), and measures the intensity of the laser light 109 reflected by the thin-sheet portion 101 (upward arrow). Thus, the laser sensor 41 calculates a reflectance R of the laser light 109. The reflectance R is defined by R=Ir/Ii wherein Ii represents the amount of light of the laser light 109 emitted from the laser sensor 41 (downward arrow), and Ir represents the amount of light of the laser light 109 entering the laser sensor 41 (upward arrow).

As shown in FIG. 5A, when the thin-sheet portion 101 of the wafer does not warp, when the laser light 109 emitted from the laser sensor 41 is incident on an upper surface 101a of the thin-sheet portion 101 from a direction normal to the upper surface 101a, it is reflected vertically by the upper surface 101a, and mostly reflects back towards the laser sensor 41. Thus, the reflectance R is relatively high.

On the other hand, as shown in FIG. 5B, when the thin-sheet portion 101 warps, the laser light 109 emitted from the laser sensor 41 is incident on the upper surface 101a from a direction inclined with respect to a normal 101n to the upper surface 101a. Then, the laser light 109 is reflected in a direction inclined to the opposite side of the incident direction with respect to the normal 101n, refracted by the surface of the liquid 105, and thus travels in a direction deviating away from the direction toward the laser sensor 41. Consequently, the light amount of the laser light 109 returning to the laser sensor 41 is relatively small, and the reflectance R is relatively low.

Accordingly, by calculating the reflectance R, it is possible to evaluate the amount of warpage of the thin-sheet portion 101. Then, by feeding the evaluation results back to a liquid supply apparatus 14, the thin-sheet portion 101 of the wafer may be kept flat by adjustments in fluid amounts, pressures, or types. Thus, even when the amount of warpage of the thin-sheet portion 101 differs because the thickness of the thin-sheet portion 101 differs from batch to batch, or the kind and ejection conditions of the liquid 105 differ, the amount of warpage is measured in situ (in-situ monitoring) and fed back, thereby being able to flatten the thin-sheet portion 101 with high precision. The configuration, operation, and effects other than those above in the embodiment are otherwise similar to those in the first embodiment.

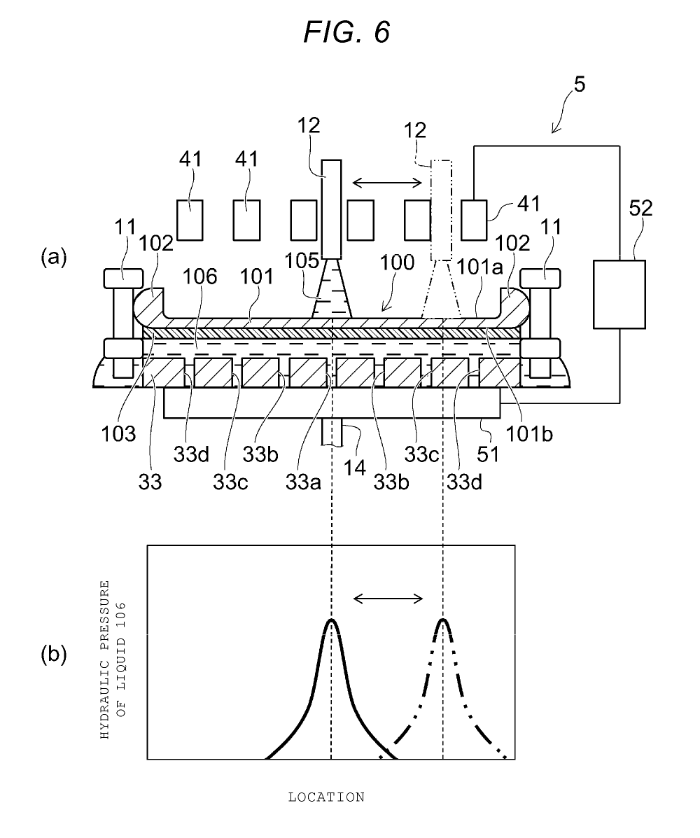

FIG. 6 is a diagram having a portion (a) illustrating a semiconductor device manufacturing apparatus according to a fifth embodiment. FIG. 6 also includes a portion (b) that is a graph showing the in-plane distribution of hydraulic pressure with the location in a wafer plane on the horizontal axis, and with the hydraulic pressure of a liquid 106 on the vertical axis.

As shown in portion (a) of FIG. 6, in a semiconductor device manufacturing apparatus 5 according to the fifth embodiment, a plate 33 like the one described in the third embodiment is provided. The plate 33 is formed with a plurality of ejection openings 33a to 33d in concentric arrangements. Further, in the manufacturing apparatus 5, a plurality of laser sensors 41 like that described with respect to the fourth embodiment is provided. Moreover, in the manufacturing apparatus 5, a hydraulic pressure control apparatus 51 for controlling the pressures of the liquid 106 that is supplied to the ejection openings 33a to 33d independently from each other is provided between a liquid supply apparatus 14 and the plate 33. The hydraulic pressure control apparatus 51 may control the flow rates instead of the pressures of the liquid 106. Furthermore, a controller 52 connected to all the laser sensors 41 and the hydraulic pressure control apparatus 51 is provided. In the manufacturing apparatus 5, the position of a nozzle 12 may be movable in a radial direction of the wafer 100.

In the manufacturing apparatus 5, the nozzle 12 can move in the radial direction of the wafer 100, thus changing the distribution of force applied by the liquid 105 to the wafer 100 and changing the warping state of the thin-sheet portion 101. On the other hand, in the manufacturing apparatus 5, the laser sensors 41 determine reflectances R at portions of the thin-sheet portion 101, and output the reflectances R to the controller 52. The controller 52 evaluates the state of warpage of the thin-sheet portion 101, then determines the pressure distribution of the liquid 106 based on this, and outputs a control signal to the hydraulic pressure control apparatus 51. Based on the control signal transmitted from the controller 52, the hydraulic pressure control apparatus 51 controls individual hydraulic pressures of the liquid 106 that is supplied to the ejection openings 33a to 33d in the plate 33. Thus, the pressure distribution of the liquid 106 may be controlled in real time based on the output of the laser sensors 41 and other input variables. For example, as shown in portion (b) of FIG. 6, in accordance with the movement of the nozzle 12, the peak of the hydraulic pressure distribution of the liquid 106 may be moved.

By dynamically controlling the pressure distribution of the liquid 106 in this manner, an upward force applied by the liquid 106 to the thin-sheet portion 101 is continuously adjusted to balance against a downward force applied by the liquid 105 to the thin-sheet portion 101. Thus, the manufacturing apparatus 5 is able to keep the thin-sheet portion 100 flat with high precision. The configuration, operation, and effects other than those above in the fifth embodiment are otherwise similar to those in the first embodiment.

In any of the embodiments, the liquid 105 may be replaced with a gas, and the liquid 106 may also be replaced with a gas. That is, a combination of a fluid ejected toward the upper surface 101a of the thin-sheet portion 101 and a fluid ejected toward the lower surface 101b may be chosen as desired. “Fluid” in this context includes a liquid or a gas and mixed phases thereof. The embodiments have shown the example in which the processing liquid 105 is ejected toward the upper surface 101a of the thin-sheet portion 101, and the supporting liquid 106 is ejected toward the lower surface 101b of the thin-sheet portion 101, but the scope of the present disclosure is not limited to this arrangement. For example, the upper and lower relationship may be reversed. Further, it should be noted the disclosed embodiments may be combined with each another for implementation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing apparatus, comprising:
a chuck for contacting a peripheral portion of a workpiece;
a nozzle configured to eject a first fluid toward a first surface while the workpiece is in contact with the chuck; and
a plate having an opening configured such that a second fluid can be ejected toward a second surface of the workpiece while the workpiece is in contact with the chuck, the second surface being opposite the first surface.

2. The apparatus according to claim 1, wherein the plate is provided with a plurality of openings configured such that the second fluid can be ejected toward the second surface of the workpiece while the workpiece is in contact with the chuck.

3. The apparatus according to claim 2, wherein the flow rates or pressures of the second fluid are controlled for each opening in the plate.

4. The apparatus according to any claim 3, further comprising:
a sensor configured to evaluate a displacement of the workpiece by emitting light toward the interior portion and measuring the intensity of the light reflected by the interior portion.

5. The apparatus according to claim 1, further comprising:
a sensor configured to evaluate a displacement of the workpiece by emitting light toward the interior portion and measuring the intensity of the light reflected by the interior portion.

6. The apparatus according to claim 1, wherein the chuck is configured to cause the workpiece to rotate.

7. The apparatus according to claim 1, wherein the second fluid is a liquid.

8. The apparatus according to claim 1, wherein the nozzle is movable.

9. A semiconductor device manufacturing method, comprising:
holding a peripheral portion of a workpiece with a chuck, the peripheral portion surrounding an interior portion of the workpiece; and
ejecting a first fluid toward a first surface of the interior portion to control a displacement of the interior portion in a direction perpendicular to a plane of the workpiece.

10. The method according to claim 9, wherein a second surface of the interior portion is subjected to a second fluid while the first fluid is being ejected toward the first surface of the interior portion to control the displacement of the interior portion.

11. The method according to claim 9, wherein the first fluid is simultaneously ejected toward a plurality of areas of the first surface.

12. The method according to claim 11, wherein at least one of a flow rate and a pressure of the first fluid is controlled for each area in the plurality of areas of the first surface.

13. The method according to claim 9, wherein the displacement of the workpiece is evaluated by emitting laser light toward the interior portion of the workpiece, and measuring the intensity of the laser light reflected from the interior portion of the workpiece.

14. The method according to claim 9, wherein the wafer is rotated while the peripheral portion of the wafer is in contact with the chuck.

15. The method according to claim 9, wherein the chuck comprises a plurality of chuck portions.

16. The method according to claim 9, wherein the first fluid is a gas.

17. A method of processing a workpiece, comprising:
processing a first surface on a first side of an interior portion of a workpiece by subjecting the first surface to a first fluid while a peripheral portion of the workpiece is in contact with a chuck; and
subjecting a second surface on a second side of the interior portion of the workpiece to a second fluid to counteract a displacement of the interior portion in a direction perpendicular to a plane of the workpiece.

18. The method of claim 17, wherein the processing of the first surface is any one of a cleaning process, an etching process, and a coating process.

19. The method of claim 17, further comprising:
detecting the displacement of the interior portion in the direction perpendicular, and adjusting at least one of a pressure of the second fluid and a flow rate of the second fluid to counteract the detected displacement.

20. The method of claim 17, wherein the second fluid is supplied from a plurality of openings in a plate facing the second surface.
